(19) United States
(12) Patent Application Publication
(10) Pub. No.: US 2020/0350388 A1
(43) Pub. Date: Nov. 5, 2020

(54) DISPLAY PANEL, DISPLAY SCREEN, AND DISPLAY TERMINAL

(71) Applicant: KUNSHAN GO-VISIONOX OPTO-ELECTRONICS CO., LTD., Kunshan (CN)

(72) Inventors: Yanqin SONG, Kunshan (CN); Lu ZHANG, Kunshan (CN); Xiaoyang TONG, Kunshan (CN)

(21) Appl. No.: 16/934,022

(22) Filed: Jul. 21, 2020

Related U.S. Application Data
(63) Continuation of application No. PCT/CN2019/076302, filed on Feb. 27, 2019.

(30) Foreign Application Priority Data
Sep. 30, 2018 (CN) 201811160611.7

(51) Int. Cl. H01L 27/32

(52) U.S. Cl. CPC H01L 27/3272; H01L 27/3276; H01L 27/3246; H01L 27/3234

(57) ABSTRACT

The application relates to a display panel, a display screen and a display terminal. A first electrode in the display panel has a one-to-one correspondence with a pixel circuit, the second electrode is a full-surface electrode, and a scan line and a data line are connected to the pixel circuit, and the scan line controls the turning on and turning off of the pixel circuit. When the pixel circuit is turned on, the data line provides a driving current for the first electrode to control the sub-pixel to emit light. The pillar on the pixel defining layer at least partially covers the active layer in the pixel circuit. The pillar is made of a non-specular reflective material; and the reflectivity of the material of the pillar is less than the reflectivity of a metal, and/or the material of the pillar is a low light transmittance material.

### RELATED APPLICATIONS

This application is a continuation application to PCT Application No. PCT/CN2019/076302, filed on Feb. 27, 2019, which claims priority to Chinese Patent Application No. 201811160611.7, filed on Sep. 30, 2018. Both applications are incorporated by reference herein for all purposes.

### TECHNICAL FIELD

The present application relates to the field of display technologies.

### BACKGROUND

With rapid development of the display terminal, users have an increasingly higher demands for the screen-to-body ratio. Since cameras, sensors, earpieces, etc. are needed to be installed on the upper part of the screen, conventionally, the upper part of the screen need to be removed to prevent the cameras, sensors, earpieces, etc. from be covered by the screen. The lack of the upper part worsens the overall uniformity of the screen, which further worsens the users' experiences. Therefore, the full display screen with better overall uniformity has received more and more attention now.

### SUMMARY

To solve the above problems, embodiments of the present application provide a display panel, a display screen, and a display terminal that have an improved the display effect of full screen.

In a first aspect, an embodiment of the present application provides a display panel which comprises:

a substrate; a pixel circuit disposed on the substrate; a first electrode layer disposed on the pixel circuit and comprising a plurality of first electrodes; a pixel defining layer disposed on the first electrode and having a plurality of openings thereon; a pillar disposed on the pixel defining layer and at least partially covering an active layer and/or a metal layer in the pixel circuit; a second electrode, disposed on a light emitting structure layer; a scanning line and a data line, both connected to the pixel circuit; and the pixel circuit has a one-to-one correspondence with the first electrode, a light emitting structure layer is arranged in the opening of the pixel defining layer to form a plurality of sub-pixels, and the sub-pixel has a one-to-one correspondence with the first electrode, and the pillar is made of a non-specular reflective material, and the reflectivity of the non-specular reflective material of the pillar is less than the reflectivity of a metal, and/or the pillar is made of a low light transmittance material, the scanning line provides a voltage to the pixel circuit to control the turning on and turning off of the pixel circuit, and when the pixel circuit is turned on, a drive current from the data line is directly supplied to the first electrode to drive the sub-pixels to emit light.

In one of the examples of the present application, the second electrode is a face electrode.

In one of the examples of the present application, the material of the pillar has a light transmittance of less than 20%.

In one of the examples of the present application, the material of the pillar has a reflectivity of less than 20%.

In one example of the present application, the pillar is made of a black organic adhesive.

In one of the examples of the present application, each sub-pixel region comprises a light-emitting area and the pixel circuit area, and size of a projection area of the pillar in the sub-pixel region is less than 50% size of an area of the pixel area.

In one of the examples of the present application, each side of the pillar is an arc.

In one of the examples of the present application, the pillar is a cylindrical pillar (SPC) or an elliptical cylindrical SPC; preferably a cylindrical SPC.

In one of the examples of the present application, the pixel circuit comprises only a switching device.

In one of the examples of the present application, the pixel circuit comprises one switching device, and the switching device comprises a first terminal, a second terminal, and a control terminal; and the scanning line is connected to the control terminal of the switching device, the data line is connected to the first terminal of the switching device, and the first electrode is connected to the second terminal of the switching device.

In one of the examples of the present application, the first electrode is an anode, the second electrode is a cathode, the switching device is a driving thin film transistor (TFT), and the first terminal is a source or a drain of the driving TFT, the second terminal is a drain or a source of the driving TFT, the control terminal is a gate of the driving TFT; and the driving TFT has a top gate structure or a bottom gate structure.

In one of the examples of the present application, one or more of the first electrode, the second electrode, the data line, and the scanning line are made of a transparent conductive material and the light transmittance of the transparent conductive material is greater than 90%.

In one of the examples of the present application, the scanning line and/or data line are made of an indium tin oxide (ITO) material or an indium zinc oxide (IZO) material.

In one of the examples of the present application, when the gate is made of the transparent conductive material, the scanning line and the gate are formed in the same step; or when the gate is made of a metal material, the scanning line is disposed above or below the gate.

In one of the examples of the present application, the data line and the first electrode are formed in the same step.

In one of the examples of the present application, a plurality of the scanning lines extend in parallel along a first direction, a plurality of the data lines extend in parallel along a second direction, the first direction intersects with a second direction and at least one side of the scanning line and/or the data line in the extending direction thereof has a wave shape.

In one of the examples of the present application, a first pitch is arranged between adjacent scanning lines, and the first pitch changes continuously or intermittently; and/or, a second pitch is arranged between adjacent data lines, and the second pitch changes continuously or intermittently; and/or the width of the scanning line changes continuously or intermittently; and/or the width of the data line changes continuously or intermittently.

In one of the examples of the present application, both sides of the scanning line in the extending direction has a wave shape, and wave peaks of the two sides are oppositely disposed, and wave troughs are oppositely disposed; and/or two sides of the data line in the extending direction have a wave shape, and the wave peaks of the two sides are oppositely disposed, and the wave troughs are oppositely disposed.

In one of the examples of the present application, a first connecting portion is formed at a corresponding position of the wave trough of the scanning line; and the first connecting portion is strip-shaped; and/or a second connecting portion is formed at a corresponding position of the wave trough of the data line, and the second connecting portion is strip-shaped; and/or the first connecting portion is an electrical connecting area of the scanning line and the switching device; and/or the second connecting portion is an electrical connecting area of the data line and the switching device.

In one of the examples of the present application, the first electrode is circular, an elliptical or a dumbbell shaped.

In one of the examples of the present application, the sub-pixels are circular, elliptical or dumbbell shaped.

In a second aspect, an embodiment of the present application provides a display screen, comprising at least a first display area and a second display area, and each display area is used for displaying a dynamic or static picture, and a photosensitive device is disposed below the first display area; and the first display area is provided with the display panel of claim 1, and the second display area is provided with a passive matrix organic light emitting diode display panel (PMOLED) or an active matrix organic light emitting diode display panel (AMOLED).

In one of the examples of the present application, when the display panel disposed in the second display area is an AMOLED display panel, the cathode of the display panel of the first display area and the cathode of the display panel of the second display area share a whole surface electrode.

In a third aspect, the present application provides a display terminal, comprising an apparatus body having a device area; the display screen descripted in the second aspect above covering the apparatus body; and the device area is located below the first display area and provided with a photosensitive device for collecting light through the first display area.

In one of the examples of the present application, the device area is a device region; and the photosensitive device comprises a camera and/or a light sensor.

The display panel provided by the present application comprises a substrate; a pixel circuit, disposed on the substrate; a first electrode layer, disposed on the pixel circuit and comprising a plurality of first electrodes; a pixel defining layer, disposed on the first electrode and having a plurality of openings thereon; a pillar, disposed on the pixel defining layer and at least partially covering an active layer and/or a metal layer in the pixel circuit; a second electrode, disposed on a light emitting structure layer; a scanning line and a data line, both connected to the pixel circuit; and the pixel circuit has a one-to-one correspondence with the first electrode, a light emitting structure layer is arranged in the opening of the pixel defining layer to form a plurality of sub-pixels, and the sub-pixel has a one-to-one correspondence with the first electrode, and the pillar is made of a non-specular reflective material, and the reflectivity of the non-specular reflective material of the pillar is less than the reflectivity of a metal, and/or the pillar is made of a low light transmittance material, the scanning line provides a voltage to the pixel circuit to control the turning on and turning off of the pixel circuit, and when the pixel circuit is turned on, a drive current from the data line is directly supplied to the first electrode to drive the sub-pixels to emit light. The pillar in the display panel at least partially covers the active layer and/or the metal layer in the pixel circuit, and the pillar can effectively absorb the light reflected by the corresponding region of the active layer and/or metal layer, thereby avoiding the light reflected in the screen caused by the light reflected in the active layer and/or metal layer when the screen is exposed to external light, thereby worsening the display effect of the full display screen.

### BRIEF DESCRIPTION OF THE DRAWINGS

In order to more clearly illustrate the embodiments of the present application, the drawings used in the embodiments will be briefly described below. Obviously, the drawings attached in the following description only represent some examples of the present application, and those skilled in the art can obtain other drawings based on these drawings without any creative intellectual work.

FIG. 1 is a schematic view showing a specific example of a display panel in the Embodiment of the present application;

FIG. 2 is a schematic view showing another specific example of a display panel in the Embodiment of the present application;

FIG. 3 is a schematic view showing another specific example of a display panel in the Embodiment of the present application;

FIG. 4A is a schematic view showing another specific example of a display panel in the Embodiment of the present application;

FIG. 4B is a schematic view showing another specific example of a display panel in the Embodiment of the present application;

FIG. 5 is a schematic view of a specific example of a scanning line of a display panel in the Embodiment of the present application;

FIG. 6 is a schematic view showing another specific example of a scanning line of a display panel in the Embodiment of the present application;

FIG. 7 is a schematic view showing another specific example of a scanning line of a display panel in the Embodiment of the present application;

FIG. 8 is a schematic view of a specific example of a first electrode of a display panel in the Embodiment of the present application;

FIG. 9 is a schematic view showing another specific example of a first electrode of a display panel in the Embodiment of the present application;

FIG. 10 is a schematic view showing another specific example of a first electrode of a display panel in the Embodiment of the present application;

FIG. 11 is a flow chart showing a specific example of the opening of a pixel defining layer of a display panel in the Embodiment of the present application;

FIG. 12 is a flow chart showing a specific example of a method of forming a display panel in the Embodiment of the present application;

FIG. 13 is a flow chart showing a specific example of forming a plurality of switching devices, scanning lines, and data lines on a substrate in a method of forming a display panel in the Embodiment of the present application;

FIG. 14 is a schematic structural view showing a specific example of a switching device in the Embodiment of the present application;

FIG. 15 is a schematic structural view showing another specific example of the switching device in the Embodiment of the present application;

FIG. 16 is a structural view of a specific example of a display panel formed by a method of forming a display panel in the Embodiment of the present application;

FIG. 17 is a flow chart showing another specific example of forming a plurality of switching devices, scanning lines, and data lines on a substrate in the method of forming a display panel in the Embodiment of the present application;

FIG. 18 is a structural view showing another specific example of a display panel formed by the method of forming a display panel in the Embodiment of the present application;

FIG. 19 is a flow chart showing a specific example of forming a plurality of sub-pixels having a one-to-one relationship with a plurality of switching devices on the plurality of switching devices in the method of forming a display panel in the Embodiment of the present application;

FIG. 20 is a schematic view showing a specific example of a display screen in the Embodiment of the present application;

FIG. 21 is a schematic view of a specific example of a display terminal in the Embodiment of the present application;

FIG. 22 is a schematic structural view of an apparatus body in the Embodiment of the present application.

### DETAILED DESCRIPTION

In order to make the objects, technical solutions and advantages of the application more clear, the present application will be further described in detail below with reference to the drawings and embodiments. It should be understood that the embodiments described herein are merely illustrative of the application and are not intended to limit the scope of the present application.

In the description of the present application, it should be understood that the orientation and positional relationship indicated by the terms “center”, “transverse”, “upper”, “lower”, “left”, “right”, “vertical”, “horizontal”, “top”, “bottom”, “inside” and “outside” are based on the drawings. And the terms are merely used for describing the present application and simplifying the description for convenience rather than limiting the construction and operation of the device or the element to a particular and certain orientation. Therefore these terms should not be understood as limiting the scope of the present application. In addition, it should be noted that when an element is described as “formed on another element” or “connected to another element”, the element can be directly connected to the other element without any element or connected to the other element through a middle element. When an element is described as “directly on another element”, the element should be directly connected to the other element without any elements.

As described in the background, since it is necessary to install components such as a camera, a sensor, an earpiece, and the like on upper part of the screen, it is conventionally required to reserve certain area on the upper part of the screen for installing the above components, but this area installed the above components cannot be used for displaying any more, therefore it is difficult to achieve the target of the full display screen in a true sense.

Based on this, an embodiment of the present application provides a display panel, and a photosensitive element such as a camera can be disposed below the display panel. The display panel can effectively reduce the reflection of the light from the opaque layer such as the active layer or the metal layer, and improve the display effect and the photographing effect of this area, thereby achieve the target of the full display screen in a true sense.

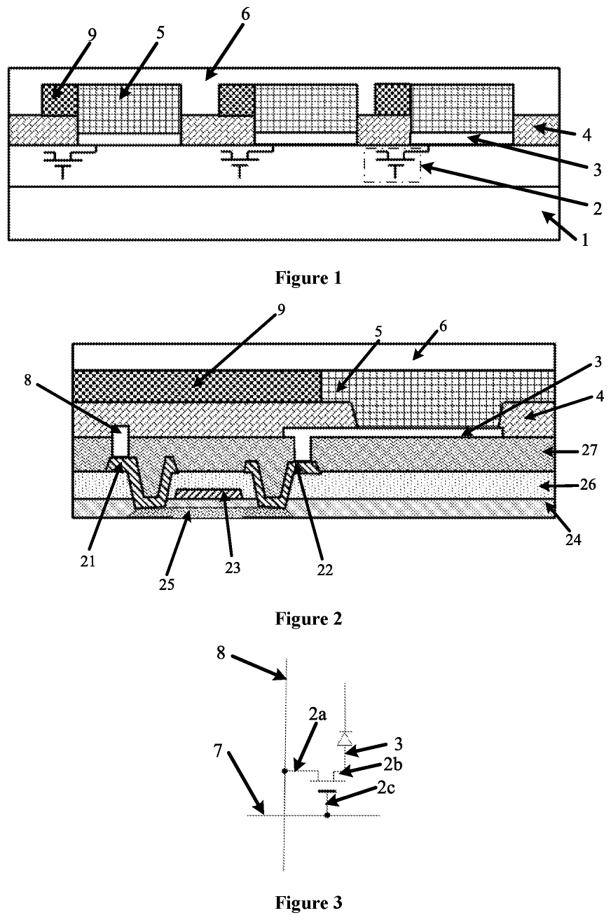

FIG. 1 and FIG. 2 are sectional views of the display panel according to an embodiment of the present application, as shown in FIG. 1 and FIG. 2, the display panel comprises a substrate 1 and a pixel circuit 2 disposed on the substrate 1; the pixel circuit 2 is provided with a first electrode layer. The first electrode layer comprises a plurality of first electrodes 3, and the first electrodes 3 have an one-to-one correspondence with the pixel circuits 2, and the first electrode is an anode and the first electrode layer is an anode layer. The display panel further comprises the pixel defining layer 4 disposed on the first electrode 3. The pixel defining layer 4 has a plurality of openings and the light emitting structure layers 5 are disposed in the openings to form a plurality of sub-pixels. The sub-pixels have a one-to-one correspondence with the first electrodes 3. A pillar 9 is disposed above the pixel defining layer 4 at least partially cover the active layer in the pixel circuit 2 and/or pillar at least partially cover the metal layer in the pixel circuit 2. The pillar 9 is made of a non-specular reflective material; and the reflectivity of the non-specular reflective material of the pillar 9 is less than the reflectivity of a metal, and/or the material of the pillar 9 is made of a low light transmittance material. A second electrode 6 is disposed above the light-emitting structure layer 5, and the second electrode 6 is a cathode which is a surface electrode made of an entire surface electrode material. A scanning line and a data line are both connected to the pixel circuit 2, and the scanning line supplies a voltage to the pixel circuit 2 to control the on-off state of the pixel circuit 2. When the pixel circuit 2 is turned on, a drive current from the data line is directly supplied to the first electrode 3 to control light emission of the sub-pixel.

The pillar 9 cover at least the active layer and/or the metal layer in the pixel circuit, and the pillars are made of non-specular reflective material; and the reflectivity of the non-specular reflective material of the pillars 9 is less than the reflectivity of the metal, and/or the pillar 9 is made of a low light transmittance material, and the pillar 9 can effectively absorb the light reflected by the corresponding area of the active layer and/or the metal layer, thereby avoiding the light reflected in the screen caused by the light reflected in the active layer and/or metal layer when the screen is exposed to external light, which further worsens the display effect of the full display screen. Moreover, due to the shielding effect of the pillars 9, the light reflection of the active layer and/or the metal layer can be effectively reduced, so that external light can't go into the pixel circuit to worsen the performance of the pixel circuit switching device.

In addition, the scanning line controls the on-off state of the pixel circuit, through a switching voltage required by the pixel circuit, the load current of the scanning line decrease greatly. When the pixel circuit is turned on, the driving current is supplied to the anode through the data line to make the sub-pixel to emission. The data line only needs to supply the driving current for only one sub-pixel at each time, so that the data line is less loaded. A plurality of sub-pixels share the same surface electrode (cathode) and the currents of one row of sub-pixels are provided by the whole surface cathode at each time, so that the conductivity requirements for the cathode decline greatly, and electrodes with high transparency improve the overall uniformity of the screen.

It should be noted that the pillar 9 may partially or completely covers the active layer and/or the metal layer in the pixel circuit 2. In an embodiment, the pillar 9 may partially or completely covers the metal layer in the pixel circuit 2. In the another embodiment, the pillar 9 may also partially or completely covers the active layer in the pixel circuit 2. In addition, the pillar 9 can also cover the metal layer and the active layer at the same time, in the same covering mode or in the different covering mode. The covering mode and the covering area in this embodiment are only for the purpose of illustration but not limited to the present application.

In an optional embodiment, the reflectivity of the material of the pillar is less than 20%; the reflectivity of the material of the pillar influences the visual effect of the display screen, and the lower the reflectivity is, the worse the reflective effect of the pillar becomes, and the better the overall visual effect of the display screen becomes.

In an alternative embodiment, the material of the pillar has a light transmittance of less than 20%; excessive light transmittance worsens the characteristics of the TFT transistors in the pixel circuit, thereby worsening performance of the transistors.

It should be noted that, in actual use, the selected material of the pillar can satisfy the requirements of reflectivity and light transmittance at the same time, so that most of the reflected light can be absorbed to achieve better display effect.

In an alternative embodiment, the pixel circuit is generally composed of switching devices, the switching device can be a driving TFT. The gate electrode, source electrode and drain electrode of the driving TFT in a conventional fabrication process, such as a Low Temperature Polycrystalline Silicon Thin Film Transistor (LTPS) process are usually made with metal. The transparency of the metal layer is low, so that when the external light is irradiated, the screen reflects the light, which worsens the display effect of the screen. Therefore, the pillar in the display panel of the present embodiment further covers the metal layer in the pixel circuit to prevent the metal layer from reflecting the light when it is exposed to the external light, thereby further improving the display effect of the display screen. Specifically, the gate, the source electrode, and the drain electrode in the pixel circuit are all made of metal, and the pillar partial or completely covers the active layer and the metal layer.

In an alternative embodiment, the gate electrode, the source electrode or the drain electrode of the pixel circuit can be made of transparent material (such as ITO). For example, the gate electrode in the pixel circuit can be made of a transparent material, and the source and the drain are made of a metal layer. In this case, in order to reduce the size of the area of pixel circuit covered by the pillar and improve the transparency of the display, the pillar only needs to cover the source drain and the active layer. For example, in the pixel circuit, the gate, the source and the drain are all made of a transparent material, and the pillar only needs to cover the active layer, and the size of the area of pixel circuit covered by is further reduced, so that the transparency of the display area above the photosensitive element can be improved while preventing reflection.

It should be noted that in order to achieve a better transparency and reduce the light reflected from the metal layer and the active layer at the same time, the metal layer in the transparent screen should be concentrated together as much as possible in the pixel circuit layout design. For example, the space between the source and the active layer or the space between the drain and the active layer is a minimum process size by the chosen process. Furthermore, the above design of the pixel circuit layout will cost less metal layer as possible. For example, the gate is connected to the scanning line, and the scanning line is arranged as close as possible to the gate, so that the wiring of the gate can be reduced and the size of the covering area of the metal layer can be reduced, thereby reducing the size of the covering area of the pillar, and improving the transparency of the display are above the photosensitive element. Certainly, in other examples, other conventional methods capable of reducing the area of the metal layer or active layer or concentrating the metal layer or active layer the may be accepted, and falls within the scope of the present application.

In an alternative embodiment, each of the sub-pixel regions comprises a light-emitting area and a pixel circuit area, and size of a projection area of the pillar on the sub-pixel region is less than 50% size of the area of the pixel area, and transparency of the display area above the photosensitive element can be ensured while reducing the reflected light, so that a good compromise between the reflected light and the transparency can be realized. In an alternative example, the pillar is located outside of the opening to increase an aperture opening ratio as much as possible, thereby improving the display effect of the display screen.

In an alternative embodiment, each side of the pillar is a circular arc, so that no slit will be formed between the pillar and the surrounding structure of each layer, thereby weakening the diffraction effect, and further ensuring that the images obtained by the camera disposed below the display panel can achieve a higher definition. Preferably, the pillar is cylindrical shape, and the manufacture process is simple and easy to be done. The cylindrical shape of the pillar is helpful to further reduce the light reflection, and weaken the diffraction effect, thereby ensuring that the images obtained by a camera have higher definition when the camera is disposed below the display panel. Certainly, in other embodiments, the shape of the pillar can also be appropriately adjusted as required, such as a cylindrical shape or an elliptical cylindrical shape. Preferably, the pillar is provided in a cylindrical shape, and a better weakening effect of the diffraction can be achieved, but the present example is not limited thereto.

In an alternative embodiment, the pixel circuitry is arranged adjacent to the scanning lines, and the size of metal wiring in the pixel circuit is reduced to make the layout of the metal layers more compact.

The metal layer and the active layer in the above transparent screen are concentrated together as much as possible, and then a black organic adhesive layer is deposited on a relatively concentrated area of the metal wire to form a pillar to prevent light reflection from the metal layer and the active layer when exposed to the external light, thereby improving the display effect of the full screen.

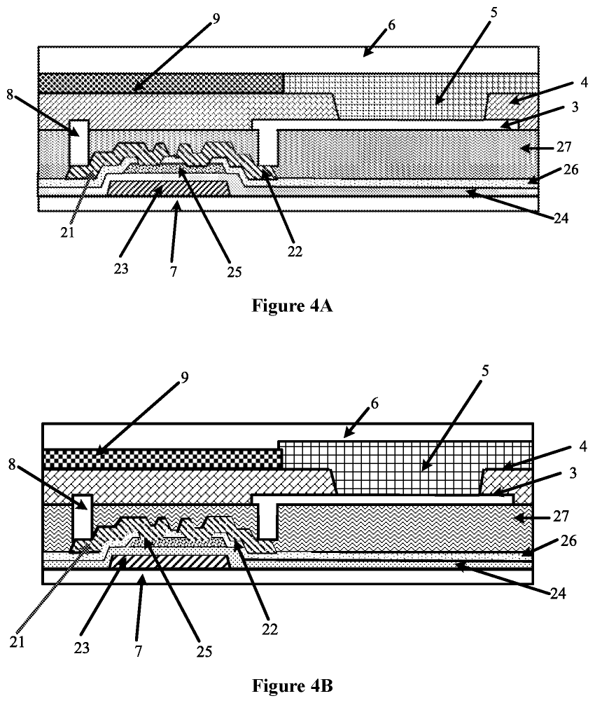

The light emitting structure layer is located above the pixel circuit, and the relative relationship between the light emitting structure layer 5 and the pillar 9 can be reasonably set as required. In an embodiment, the light emitting structure layer 5 may not cover the pillars 9, as shown in FIG. 4A. In the another embodiment, the light emitting structure layer 5 may cover the pillars 9, as shown in FIG. 4B, the area covering on the pillar by the light emitting structure layer 5 can be adjusted as needed, which is not limited in this example.

In an embodiment, the substrate 1 may be a rigid substrate, such as a transparent substrate comprising a glass substrate, a quartz substrate, or a plastic substrate; the substrate 1 may also be a flexible substrate, such as a PI film, to improve the transparency of the device.

In an embodiment, the light emitting structure layer may be an Organic Light-Emitting Diode (OLED).

In an alternative embodiment, unlike the pixel circuit of a conventional AMOLED, the pixel circuit 2 of the present application comprises only the switching device, and does not comprise components such as a storage capacitor. Specifically, the pixel circuit comprises only one switching device, and the switching device comprises a first terminal 2a, a second terminal 2b and a control terminal 2c, as described in detail below. A scanning line 7 is connected to the control terminal 2c of the switching device, a data line 8 is connected to the first terminal 2a of the switching device, and a first electrode 3 is connected to the second end 2b of the switching device. As shown in FIG. 3, the switching device has a one-to-one correspondence with the first electrode 3, the data line 8 is connected to the first terminal 2a of the switching device, the scanning line 7 is connected to the control terminal 2c of the switching device, and a plurality of sub-pixels have a one-to-one correspondence with a plurality of switching devices, that is one sub-pixel corresponds to one switching device. The data line is connected to the first terminal of the switching device, and the scanning line is connected to the control terminal of the switching device and the number of the switching devices in the pixel circuit is reduced to one. In the working process, only a switching voltage of the TFT needs to be input in the scanning line, but the load current of the OLED doesn't need to be input, which greatly reduces the load current of the scanning line, so that the scanning line in the present application can be made of a transparent material such as ITO. Moreover, the data line only needs to supply a current for one OLED pixel at every time, and the load is also small, therefore, the data line can also be made of a transparent material such as ITO, thereby improving the light transmittance of the display screen.

In an alternative embodiment, when the pixel circuit comprises one switching device, the switching device is a driving TFT, the first terminal 2a is the source 21 of the driving TFT, the second terminal 2b is the drain 22 of the driving TFT, and the control terminal 2c is the gate 23 of the driving TFT, and the driving TFT is a top gate structure or a bottom gate structure. In the actual manufacture process, the source 21 and the drain 22 of the TFT have a same structure and so that they can be interchanged with each other. In this embodiment, the source of the thin film transistor is used as the first terminal and the drain of the thin film transistor is used as the second terminal. Certainly, in other embodiments, the drain of the thin film transistor may be used as the first terminal, and the source of the thin film transistor may be used as the second terminal. In another alternative embodiment, the switching device may also be a Metal-Oxide-Semiconductor Field-Effect Transistor (MOSFET), and may also be other components that conventionally have switching characteristics, such as Insulated Gate Bipolar Transistor (IGBT) or the like, and the electronic components that is capable of achieving the switching function descripted in the present example and can be integrated into the display panel fall within the scope of the present application. In an alternative example, the thin film transistor may be an oxide thin film transistor or a low temperature polysilicon thin film transistor (LTPS TFT), and preferably the thin film transistor is an Indium Gallium Zinc Oxide Thin Film Transistor (IGZO TFT). The low temperature polysilicon thin film transistor has the following features comprising a high electron mobility, high resolution, simple design and better display effect; and the oxide thin film transistor has the following features comprising high light transmittance, mature process and simple manufacture.

In an alternative embodiment, when the thin film transistor is configured as a top gate structure, as shown in FIG. 2, it comprises an active layer 25, a gate insulating layer 24 disposed on the active layer 25, a gate 23 disposed on the gate insulating layer 24, an interlayer insulating layer 26 disposed on the gate 23, a source 21 and a drain 22 disposed on the interlayer insulating layer 26, and the gate 23 is connected to the scanning line. The active layer, the gate insulating layer, the gate layer, the interlayer insulating layer, the source and the drain constitute a switching device TFT, and a planarization layer 27 is disposed on the source 21 and the drain 22, and the source 21 and the drain 22 are respectively connected to the data line 8 and the first electrode 3 via through-holes on the planarization layer 27. The TFT with top gate structure requires less photolithographic masks, and the manufacture process is simple, and the cost is low.

In an alternative embodiment, when the thin film transistor is configured as a bottom gate structure, as shown in FIG. 4A, it comprises a gate 23 disposed on a scanning line 7, and the gate 23 is connected to the scanning line 7; a gate insulating layer 24, an active layer 25, and an interlayer insulating layer 26 which are sequentially stacked on the gate 23; a source 21 and a drain 22 which are disposed on the interlayer insulating layer 26; and a planarization layer 27 disposed on the source 21 and the drain 22, and the source 21 and the drain 22 are respectively connected to the data line 8 via through-holes on the planarization layer 27, and the first electrode 3 is connected to the light emitting device. The manufacture process of the bottom gate structure is complicated, and the gate and gate insulating layers of the TFT can be used as an optical protection film with good optical characteristics.

In the embodiment of the present application, the gate electrode may be made of a transparent conductive material or a metal material. The scanning line is connected to the gate. When the gate is made of a transparent conductive material, in order to simplify the process, the scanning line and the gate can be formed in the same step. In an alternative example, specifically, the scanning line and the gate are made of ITO layer, and the ITO layer is patterned by the first mask to form the scanning line and the gate at the same time, as shown in FIG. 15.

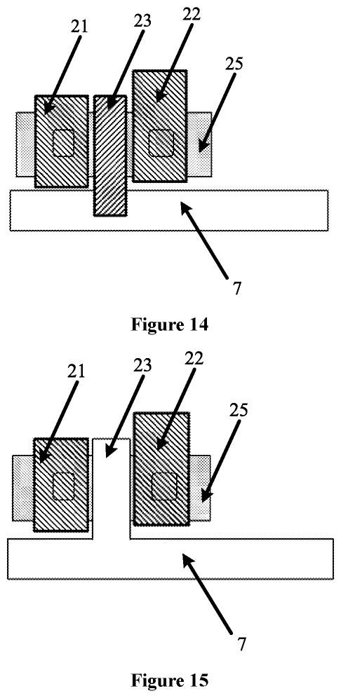

In an alternative embodiment, when the gate is made of a metal material, the scanning line may be disposed above or below the gate, thus the gate and the scanning line are required to be formed separately, as shown in FIG. 14.

In order to simplify the manufacture process, the data line and the first electrode are formed in the same step. In an alternative embodiment, specifically, the data line and the first electrode are both made of ITO layer to prepare an ITO surface, and the ITO layer is patterned by the second mask to form the data line and the first electrode at the same time. In an alternative example, the data line and the first electrode can also be formed separately when the data line and the first electrode are made of different materials.

In an alternative embodiment, in order to maximize the overall transparency of the display panel, the first electrode, the second electrode, the data line, and the scanning line are all made of a transparent conductive material, and the light transmittance of the transparent conductive material is greater than 90%. Therefore, the light transmittance of the entire display panel can exceed 70%, indicating that the display panel has higher transparency.

Specifically, the transparent conductive material of the first electrode, the second electrode, the data line and the scanning line may be indium tin oxide (ITO), indium zinc oxide (IZO), or silver-doped indium tin oxide, (Ag+ITO), or silver-doped indium zinc oxide (Ag+IZO). Since the ITO manufacture process is mature and low in cost, preferably the conductive material is indium zinc oxide. Further, in order to reduce the resistance of each conductive wiring on the basis of ensuring high light transmittance, the transparent conductive material is made of aluminum-doped zinc oxide, silver-doped ITO or silver-doped IZO.

In other alternative embodiment, the transparent conductive material may also be other conventional materials, which may be appropriately selected as required and not be limited in this embodiment. In an alternative embodiment, at least one of the first electrode, the second electrode, the data line, and the scanning line is made of a transparent conductive material.

A plurality of scanning lines extend in parallel along a first direction, a plurality of data lines extend in parallel along a second direction, the first direction intersects with the second direction, and at least one side of the scanning line and/or the data line in the extending direction thereof has a wave shape. In an alternative embodiment, the scanning line extends in the X direction, the data line extends in the Y direction, and the projections of the data line and the scanning line on the substrate are perpendicular to each other, and the two sides of the scanning line in the extending direction have a wave shape, and the two sides of the data line in the extending direction thereof also have a wave shape. The data lines and the scanning lines can generate diffraction fringes having different positions and diffusion directions, thereby weakening the diffraction effect, and further ensuring that the image obtained by the camera has a higher definition when the camera is disposed below the display panel.

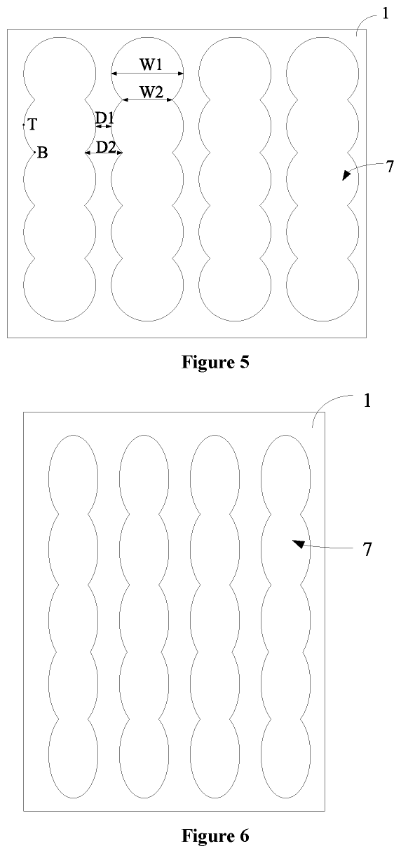

In an alternative embodiment, since the scanning lines have a wave shape, and a first pitch between the two adjacent scanning lines changes continuously or intermittently; the width of the scanning lines changes continuously or intermittently. Continuous change in width means that the widths of any two adjacent positions on the scanning line are not the same. In FIG. 5, the direction in which the scanning line extends is its lengthwise direction. The width of the scanning lines changes continuously in its extending direction. The width changes intermittently means that the widths of any two adjacent positions in a partial area on the scanning line are of the same, and the widths of the two adjacent positions in another partial area are different. In the present example, a plurality of scanning lines are regularly arranged on the substrate, and therefore, the pitch between the two adjacent scanning lines also changes continuously or intermittently in a direction parallel to the extending direction of the scanning lines. The width of the scanning line can be periodically changed in the extending direction regardless of whether the width is continuously changed or intermittently changed.

Both sides of the scanning line in the extending direction have a wave shape, and wave peaks of the two sides are oppositely disposed, and wave troughs are oppositely disposed. As shown in FIG. 5, the peaks T of the two sides in the extending direction are oppositely disposed and the wave troughs are oppositely disposed. The width between the adjacent peaks of the same scanning line is W1, and the width between the adjacent wave troughs of the same scanning line is W2. The distance between the peaks of adjacent two scanning lines is D1, and the distance between the peaks of adjacent two scanning lines is D2. In this example, both sides are connected by the same arc-shaped side. In other examples, the two sides may also be connected by the same elliptical side, as shown in FIG. 6. By setting the two sides of the scanning lines into a wave shape formed by a circular arc shape or an elliptical shape, it can ensure the diffraction fringes generated by the scanning lines can be spread in different directions, thereby not causing a more significant diffraction effect.

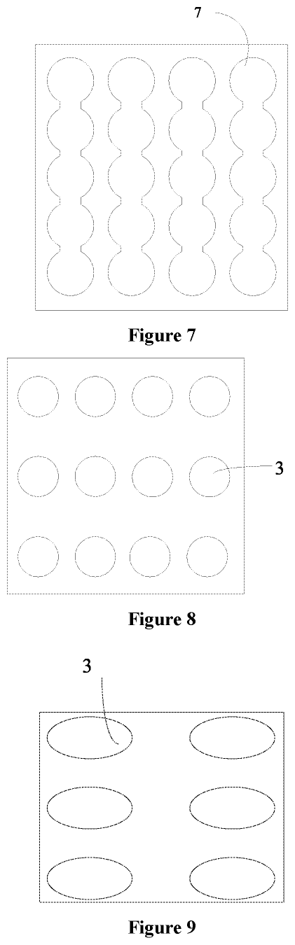

In an alternative embodiment, a first connecting portion is formed at a corresponding position of the wave trough of the wavy scanning line, and the first connecting portion may be a straight line or a curve line. As shown in FIG. 7, the first connecting portion is strip-shaped, and the first connecting portion is an electrical connecting area between the scanning line and the switching device, the control terminal of the switching device is connected to the first connecting portion. In other examples, the connecting portion may also be any other irregular shapes, such as a shape which is large at two opposite ends and small in the middle, or a shape which is small at two opposite ends and larger in the middle.

In an alternative example, since the data lines has a wave shape, a second pitch between the two adjacent data lines changes continuously or intermittently; and the width of the data lines changes continuously or intermittently. The data line is similar to the scanning line, the detailed description of the data line can be found in related parts, which are not described here. The data line can be any other wave shapes in FIGS. 5-7. The two sides of the data line in the extending direction can be wave shape, the peaks of the two sides are oppositely disposed, and the troughs are oppositely disposed. A second connecting portion is formed on a corresponding position of the troughs of the data lines, and the second connecting portion is an electrical connecting area of the data line and the switching device. The setting of the data line is similar to that of the scanning line and the details can be found in the setting of the scanning line.

The scanning lines and data lines on the display panel can be any one of the shapes as shown in FIG. 5-7 to ensure that the light can form diffraction fringes having different positions when passing through portions with different widths and different pitches of adjacent wirings in the extending direction of the data lines and the scanning lines, thereby diminishing the diffraction effect, so that the photosensitive device arranged below the display panel can work normally.

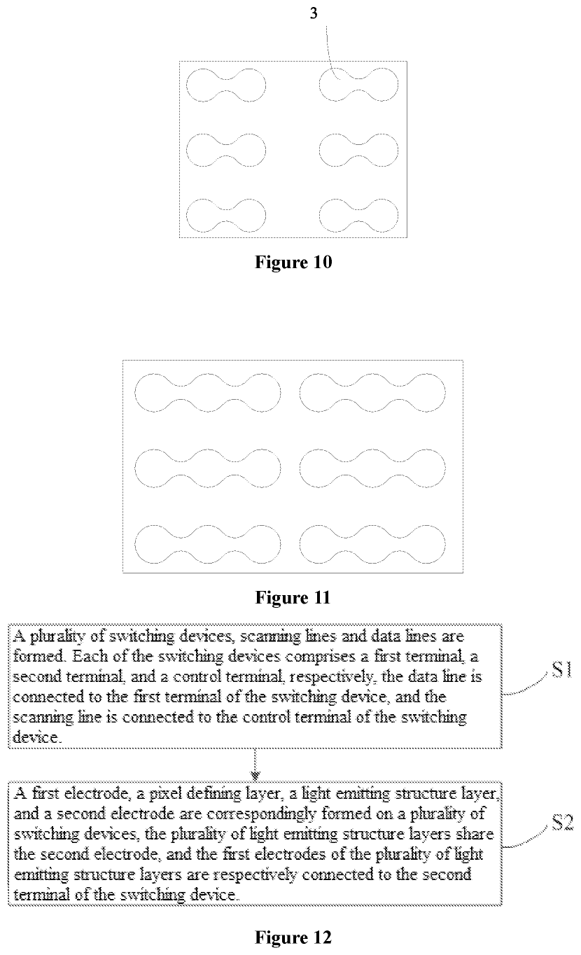

In an alternative example, the first electrode can be a shape of circular as shown in FIG. 8, or a shape of elliptical as shown in FIG. 9, or a shape of dumbbell as shown in FIG. 10. It can be understood that the first electrode can also be composed of curves having different curvature radius at different portions. Since light passes through obstacles such as slit, small hole, or disc, the light will be bent with different degrees, and the light will be deviated from the original linear direction. This phenomenon is called diffraction. During the diffraction process, the distribution of the diffraction fringes is affected by the size of the obstacle, such as the width of the slit, the size of the small hole, etc., and the positions of the diffraction fringes generated at the portions having the same width are same, so that a relatively obvious diffraction effect occurs. By changing the shape of the anode into a circular shape, an elliptical shape or a dumbbell shape, it is ensured that when light passes through the anode layer, diffraction fringes having different positions and diffusion directions can be generated at portions with different widths in the anode, thereby weakening the diffraction effect, and further ensuring the images obtained by a camera have higher definition when camera is disposed below the display panel.

The sides of the projection of the pixel defining layer on the substrate are curved and not parallel to each other, that is, the opening has a varying width in each direction and has different diffraction diffusion directions at the same portion. When external light passes the opening, diffraction fringes having different positions and diffusion directions can be generated at portion with different width, thereby avoiding significant diffraction effect, and further ensuring that the photosensitive element arranged below the display panel can be operated normally.

The openings on the conventional pixel defining layer are all configured as a rectangle or a square according to the size of the pixel. Taking a rectangular opening as an example, since the rectangle has two sets of parallel sides, the rectangle has the same width in both the length and width directions. Therefore, when external light passes through the opening, diffraction fringes having the same positions and spread directions are generated at different positions in the longitudinal direction or the width direction, so that a significant diffraction effect occurs, and the photosensitive element located below the display panel cannot work normally. The display panel in this example can solve the problem well ensuring that the photosensitive element below the display panel can work normally.

In an alternative example, the each side of the projection of the openings on the substrate has a curved shape selected from at least one of a circle, an ellipse, and other curves having varying curvatures. All the sides of the opening are curved, therefore, when the light passes through the opening, the diffraction fringes do not spread in one direction, but spread toward directions in 360°, so that the diffraction is not obvious, and the diffraction effect is improved.

In an alternative example, the shape of the projection of the opening on the substrate is circular, elliptical or dumbbell shaped or wave-shape, which is similar to the shape of the first electrode, and the detailed description can be found in the description of first electrode and FIGS. 8-10, which will not be repeated here. The shape of the projection of the opening on the substrate can be determined according to the shape of the corresponding light emitting structure. For example, the number of the opening can be determined according to the aspect ratio of the light emitting structure. In an example, the shape of projection of the opening on the substrate may also be an axisymmetric structure, thereby ensuring that each pixel on the entire display panel has a same aperture opening ratio without weakening the final display effect. As shown in FIG. 8, when the projection on the substrate is a circle, the corresponding light-emitting structure is a shape of a rectangle or a square having an aspect ratio of less than 1.5, and the symmetry axis of the projection of the opening corresponds to the symmetry axis of the corresponding light-emitting structure. The circle diameter of the projection is smaller than the minimum width of the light emitting structure. Specifically, the circle diameter of the projection can be determined according to the shape of the light emitting structure and the aperture opening ratio. Since the determination process can be performed by a conventional method of determining the size of the opening, the detailed description will be omitted here.

The aspect ratio of the sub-pixel corresponding to the opening is between 1.5 and 2.5. At this time, the projection has a dumbbell shape formed by two circles connected with each other. The two circles are respectively arranged along the length direction of the corresponding light emitting structures. In an example, there is a connecting portion between the two circles, and both sides of the connecting portion are curved, and when the light passes through the connecting portion, it can also spread in various directions, thereby improving the diffraction effect.

The aspect ratio of the light-emitting structure corresponding to the opening is greater than 2.5. At this time, the projection has a wave shape formed by three or more circles connected with each other. The three or more circles are respectively arranged along the length direction of the corresponding light emitting structures. In an example, a connecting portion is also formed in the projection. The connecting portion is an arc, that is, three or more circular is connected by an arc, thereby ensuring that light can spread in various directions when passing through the connecting portion, thereby improving the diffraction effect.

When the aspect ratio of the light-emitting structure corresponding to the opening is 1.5, the projection has a circle shape or a dumbbell shape formed by two circles connected with each other. When the aspect ratio of the light-emitting structure corresponding to the opening is 2.5, the projection has a dumbbell shape formed by two circles connected with each other, or has a wave shape formed by three circles connected with each other, as shown in FIG. 11.

In an alternative example, as shown in FIGS. 8-10, the shape of the sub-pixel is the same as the shape of the opening described above, i.e., the sub-pixel has a circle shape, an elliptical shape or a dumbbell shape. Further, the shape of the anode can also refer to the shape of the above opening, thereby further improving the diffraction effect. Certainly, the anode can also be designed in a conventional rectangular shape.

The scanning line of the display panel is connected to the control terminal of the switching device, and the scanning line only needs to provide the switching voltage to the switching device, and does not need to provide a driving current to the light emitting device, which greatly reduces the load current of the scanning line. The data line is connected to the first terminal of the switching device, and the data line only needs to supply the driving current to one sub-pixel at each moment, so the load of the data line is also small. Since the load of the data line and the scanning line are very small, the data line and the scanning line can be made of a transparent material (such as ITO) which significantly improves the transparency of the display panel. The cathode is a full-surface structure, and no negative photoresist is required, the current of one row of the OLED is provided by the full-surface cathode at each moment, so the conductivity requirement for the cathode is greatly reduced, therefore cathode with better transparency can be used to improve the transparency. The contradiction between wiring of the transparent OLED screen as well as cathode resistance and the transparency is well solved by the above technical process, and the technical process can be compatible with the manufacturing process of conventional display screen.

This example further provides a method for manufacturing a display panel. As shown in FIG. 12, the method comprises the following steps:

Step S1: a plurality of switching devices, scanning lines and data lines are formed; each of the switching devices comprises a first terminal, a second terminal, and a control terminal, respectively, the data line is connected to the first terminal of the switching device, and the scanning line is connected to the control terminal of the switching device.

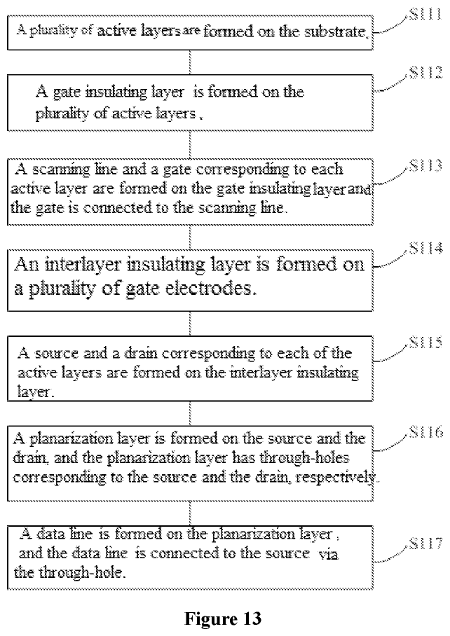

In an alternative example, the switching device is a top gate thin film transistor, as shown in FIG. 13, step S1 specifically comprises the following steps S111-S117:

Step S111: an active layer 25 is formed on the substrate 1.

In an alternative example, the substrate 1 may be a rigid one, such as transparent substrates comprising a glass substrate, a quartz substrate, or a plastic substrate; the substrate 1 may also be a flexible substrate such as a PI film or the like.

In an alternative example, a P—Si layer is formed on the substrate, and the P—Si layer comprises a shielding layer 28 and an active layer 25 which are sequentially stacked due to the technology employed. The shielding layer is used to isolate oxygen, water, and the like and at the same time, it forms a good interface with the active layer. Specifically, an entire surface of the P—Si layer is formed on the substrate, and then a photoresist is coated on the entire surface of the P—Si layer, and exposed using an active layer mask (PSI mask) to form a patterned active layer 25.

In an alternative example, the active layer may be made of a polysilicon material to form a polysilicon thin film transistor; and the polycrystalline silicon may be crystallized (e.g., using pillar solid phase crystallization) to produce a crystalline thin film transistor. In an alternative example, the active layer may also be made of amorphous silicon, which can be appropriately chosen as needed.

Step S112: a gate insulating layer 24 is formed on the plurality of active layers 25. In an alternative example, the gate insulating layer can be manufactured by a chemical vapor deposition method. Certainly, the gate insulating layer can be manufactured by other conventional methods, which is not limited in this example. The gate insulating layer may be made of silicon oxide or silicon nitride, and may be appropriately chosen as needed.

Step S113: a scanning line 7 and a gate 23 corresponding to each active layer 25 are formed on the gate insulating layer 24. The gate 23 is connected to the scanning line 7. In an alternative example, the scanning line 7 is made of indium tin oxide (ITO) material, and the gate 23 is made of a metal material, specifically, a full-surface ITO layer is formed on the gate insulating layer 24, and then a patterned scanning line 7 is formed by a mask, after which a metal gate is formed on the gate insulating layer, and the gate is located on the same layer as the scanning line and connected to the scanning line, as shown in FIG. 14. In an alternate example, the scanning line 7 is made of an indium zinc oxide (IZO) material, and may be made of other conventional transparent conductive materials. The step of forming the gate and the step of forming the scanning line may be adjusted according to the technology employed, which is not limited herein.

In another alternative example, the scanning line 7 and the gate 23 are both made of an indium tin oxide (ITO) material, specifically a full-surface ITO layer is formed on the gate insulating layer 24, and then patterning is carried out by a mask and simultaneously the scanning line 7 and the gate 23 are formed. The gate is located in the same layer as the scanning line and connected to the scanning line, and the manufacturing process is simpler and is easier to be performed, as shown in FIG. 15.

In order to reduce the diffraction, the shape of the scanning line may reference the description of display panel in this example, and the details are not described herein again.

Step S114: an interlayer insulating layer 26 is formed on a plurality of gate electrodes 23. In an alternative example, the interlayer insulating layer can be formed by a chemical vapor deposition method. Certainly, the interlayer insulating layer can be formed by other conventional methods, which is not limited in this example. The interlayer insulating layer 26 may be made of silicon oxide or silicon nitride, which may be appropriately chosen as needed.

Step S115: a source 21 and a drain 22 corresponding to each of the active layers 25 are formed on the interlayer insulating layer 26. The source 21 and the drain 22 described above may be fabricated in any conventional method. In order to ensure the performance of the TFT, the source 21 and the drain 22 are made of a metal material, such as a single-layer metal material or a metal laminate layer having good conductivity such as Ti or Ti/Al/Ti or Ag.

Step S116: a planarization layer 27 is formed on the source 21 and the drain 22. The planarization layer 27 has through-holes corresponding to the source 21 and the drain 22, respectively. The corresponding source 21 and drain 22 are exposed via the through-holes. The above planarization layer can be manufactured in any conventional manner. In an alternative example, the through-holes may be formed on the planarization layer by a wet etching process, or by other conventional methods, such as dry etching.

Step S117: a data line 8 is formed on the planarization layer 27. The data line 8 is connected to the source 21 via the through-hole. The above data line 8 can be manufactured in any conventional manner. The data line 8 is made of indium tin oxide (ITO) material, may also be made of indium zinc oxide (IZO) material, and may be made of other conventional transparent conductive materials. In order to reduce the diffraction, the shape of the data line can reference the description of the display panel in this example, and the details are not described herein again.

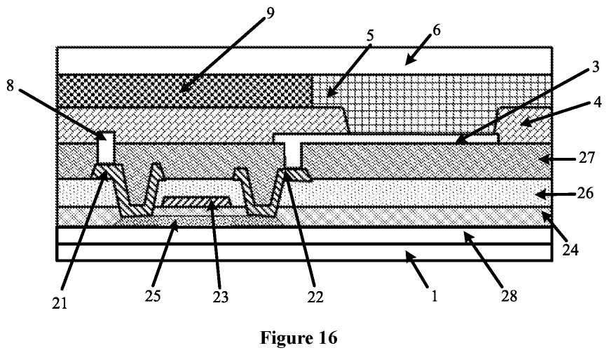

A structural view of the display panel manufactured by the above steps is shown in FIG. 16.

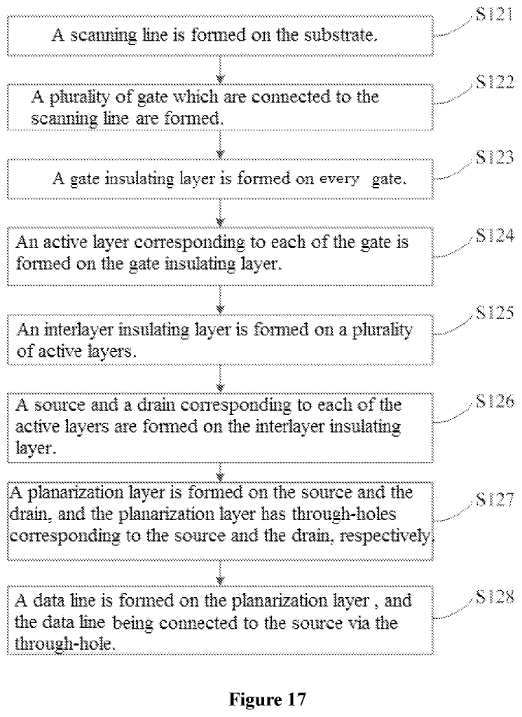

In an alternative example, when the switching device is a bottom gate thin film transistor, as shown in FIG. 17, step S1 specifically comprises the following steps S121-S128:

Step S121: a scanning line 7 is formed on the substrate 1. In an alternative example, the scanning line 7 is made of an indium tin oxide (ITO) material, specifically a full-surface ITO layer is formed on the substrate, and then a patterned scanning line 7 is formed by a mask.

In an alternative example, the substrate 1 may be a rigid substrate, such as a transparent substrate comprising a glass substrate, a quartz substrate, or a plastic substrate; the substrate 1 may also be a flexible substrate such as a PI film or the like.

Step S122: a plurality of gates 23 which are connected to the scanning line 7 are formed. The above gates can be manufactured in any conventional manner.

Step S123: a gate insulating layer 24 is formed on every gate 23. In an alternative example, the gate insulating layer can be formed by a chemical vapor deposition method. Certainly, the gate insulating layer can be formed by other conventional methods, which is not limited in this example. The gate insulating layer may be made of silicon oxide or silicon nitride, and may be appropriately chosen as needed.

Step S124: an active layer 25 corresponding to each of the gate 23 is formed on the gate insulating layer 24. The above active layer 25 can be manufactured in any conventional manner. In an alternative example, the active layer can be made of an oxide material, such as an indium gallium zinc oxide (IGZO) material.

Step S125: an interlayer insulating layer 26 is formed on a plurality of active layers 25. In an alternative example, the interlayer insulating layer can be manufactured by a chemical vapor deposition method. Certainly, the interlayer insulating layer can be formed by other conventional methods, which is not limited in this example. The interlayer insulating layer may be made of silicon oxide or silicon nitride, and may be appropriately chosen as needed.

Step S126: a source 21 and a drain 22 corresponding to each of the active layers 25 are formed on the interlayer insulating layer 26. The source 21 and the drain 22 described above may be manufactured in any conventional manner.

Step S127: a planarization layer 27 is formed on the source 21 and the drain 22, and the planarization layer 27 has through-holes corresponding to the source 21 and the drain 22, respectively, and the corresponding source 21 and drain 22 are exposed at the through-holes. In an alternative example, reference may be made to step S116.

Step S128: a data line 8 is formed on the planarization layer 27, and the data line 8 is connected to the source 21 via the through-holes. The above data line 8 can be manufactured in any conventional manner. The data line 8 is made of an indium tin oxide (ITO) material.

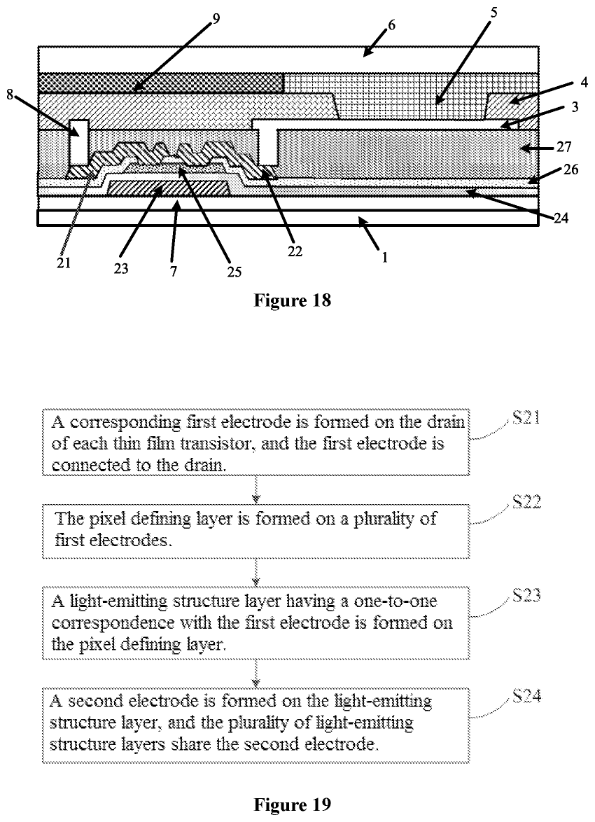

The structural view of the display panel manufactured by the above steps is as shown in FIG. 18.

Step S2: a first electrode 3, a pixel defining layer 4, a light emitting structure layer 5, and a second electrode 6 are correspondingly formed on a plurality of switching devices, the plurality of light emitting structure layers 5 share the second electrode 6, and the first electrodes 3 of the plurality of light emitting structure layers 5 are respectively connected to the second terminal 2b of the switching device.

In an alternative example, as shown in FIG. 19, step S2 specifically comprises the following steps S21-S24:

Step S21: a corresponding first electrode 3 is formed on the drain 22 of each thin film transistor, and the first electrode 3 is connected to the drain 22. In an alternative example, specifically, the first electrode 3 is formed on the planarization layer 27, and the first electrode 3 is made of an ITO material, and after the ITO material is filled into the through-hole, the ITO material is connected to the drain 22. In an alternative example, the data line and the first electrode are located in the same layer and can be manufactured simultaneously, covering the whole surface of the ITO material on the planarization layer 27, and then the patterned data line and the first electrode can be obtained through the mask. The manufacturing process is simple and cost-effective. In order to reduce the diffraction, the shape of the first electrode can reference the display panel in this example, and details are not described herein again.

Step S22: the pixel defining layer 4 is formed on a plurality of first electrodes 3. The pixel defining layer 4 comprises a plurality of openings, each of the openings corresponds to a first electrode, and the first electrode is exposed via the opening. In an alternative example, the sides of the projection of the opening formed on the pixel defining layer 4 on the substrate are curved and not parallel to each other, that is, the opening has varying widths in every direction and has different diffraction spreading directions at the same portion. When external light passes through the opening, diffraction fringes having different positions and diffusion directions can be generated at portions with different widths, thereby avoiding a significant diffraction effect, and further ensuring the photosensitive element disposed below the display panel can work normally. In order to reduce the diffraction, the shape of the opening projection can refer to the description of the display panel in this example, and details are not described herein again.

Step S23: a light-emitting structure layer 5 having a one-to-one correspondence with the first electrode 3 is formed on the pixel defining layer 4. In an alternative example, specifically, the light-emitting structure layer 5 is formed in the opening, and the light-emitting structure layer 5 can be manufactured in any conventional manner.

Step S24: a second electrode 6 is formed on the light-emitting structure layer 5, and the plurality of light-emitting structure layers 5 share the second electrode 6. In an alternative example, specifically, the whole surface of the second electrode 6 is formed on the plurality of light emitting structure layers 5 and the pixel defining layer 4. In an alternative example, the second electrode 6 can be made of an ITO material.

The example further provides a display screen, comprises at least a first display area and a second display area, each display area is used for displaying a dynamic or static picture, and a photosensitive device is disposed below the first display area; and the first display area is provided with the display panel of any of the above examples, and the second display area is provided with a PMOLED display panel or an AMOLED display panel. Since the display panels in the above examples are used in the first display area, the first display area has better transparency and the overall uniformity of the display screen is better, and when the light passes through the display area, significant diffraction effect can be avoided, thereby ensuring that the photosensitive device arranged below the first display area can work normally. It can be understood that the first display area can normally display dynamic or static pictures when the photosensitive device is not working, and the first display area is in a non-displaying state when the photosensitive device is working, thereby ensuring that light collection by the photosensitive device can be performed normally through the display panel. The transparency of the first display area is significantly improved, so that contradiction between the wiring of the transparent OLED screen and the cathode resistance with the transparency is well solved, and this design can be compatible with the manufacturing process of the normal display screen, and the production cost is low. Since a photosensitive element such as a camera can be disposed below the display panel, the application can be used to effectively reduce the reflection of the opaque layer such as the active layer or the metal layer, and improve the display effect and the shooting effect of this area, thereby realizing the full display screen in a true sense.

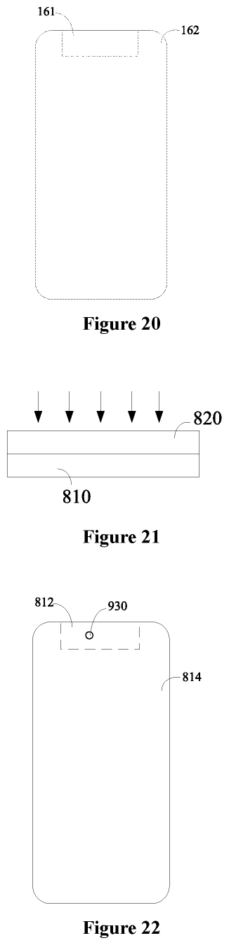

In an alternative example, as shown in FIG. 20, the display screen comprises a first display area 161 and a second display area 162, each of which is used to display a static or dynamic picture, and the display panel mentioned in any of the above Examples is used in the first display area 161, and the first display area 161 is located at the upper portion of the display screen.

In an alternative example, the display screen may further comprise three or more display areas, such as three display areas (a first display area, a second display area, and a third display area). The display panel mentioned in any of the above examples is used in the first display area. The display panel used in the second display area and the third display area is not limited in this example, and the display panels may be a PMOLED display panel or an AMOLED display panel, and certainly, the display panel of this example can also be used.

In an alternative example, when the display panel in the second display area is an AMOLED display panel, the cathode of the display panel of the first display area and the cathode of the display panel of the second display area share a whole surface electrode. A coplanar cathode makes the fabrication process simple, and the conductivity requirement of the cathode is further reduced. The electrode with better transparency can be used to improve the transparency and improve the overall uniformity of the display screen.

The example further provides a display terminal, comprising the above display screen overlaid on the apparatus body. The display terminal may be a product or a component having a display function, such as a mobile phone, a tablet PC, a television, a display screen, a palmtop computer, an iPod, a digital camera, a navigator, or the like.

FIG. 21 shows a schematic structural view of a display terminal in one Example, the display terminal comprises an apparatus body 810 and a display screen 820. The display screen 820 is disposed on the apparatus body 810 and is interconnected with the apparatus body 810. The display screen 820 can be the display screen in any of the above examples for displaying a static or dynamic picture.

FIG. 22 shows a schematic structural view of an apparatus body 810 in one example. In this example, the apparatus body 810 can be provided with a device region 812 and a non-device region 814. A photosensitive device such as a camera 930 and an optical sensor, a light sensor, or the like may be disposed in the device region 812. At this time, the display panel of the first display area of the display screen 820 is attached to the device area 812 so that the above-mentioned photosensitive device such as the camera 930 and the optical sensor can collect external light through the first display area. Since the display panel in the first display area can effectively improve the diffraction phenomenon generated by the external light passing through the first display area, thereby effectively improving the quality of the image captured by the camera 930 on the display terminal, and avoiding the image distortion of the image captured due to diffraction, while also improving the accuracy and sensitivity of the light sensor for sensing external light.

While the examples of the present application have been described with reference to the drawings, various modifications and variation can be made by those skilled in the art without departing from the spirit and scope of the application. Such modifications and variations fall within the scope defined by the claims.

What is claimed is:

1. A display panel, comprising:
a substrate;
a pixel circuit, disposed on the substrate;
a first electrode layer, disposed on the pixel circuit and comprising a plurality of first electrodes;
a pixel defining layer, disposed on the first electrodes and having a plurality of openings thereon; a pillar, disposed on the pixel defining layer and at least partially covering an active layer and/or a metal layer in the pixel circuit;
a second electrode, disposed on a light emitting structure layer;
a scanning line and a data line, both connected to the pixel circuit;
wherein the pixel circuit has a one-to-one correspondence with the first electrodes, the light emitting structure layer is disposed in the openings of the pixel defining layer to form a plurality of sub-pixels, and the sub-pixel has a one-to-one correspondence with the first electrodes, and the pillar is made of a non-specular reflective material, the reflectivity of the non-specular reflective material of the pillar is less than the reflectivity of a metal material.

2. The display panel according to claim 1, wherein the second electrode is a surface electrode, and the pillar is made of a low light transmittance material, the scanning line provides a voltage to the pixel circuit to control the turning on and turning off of the pixel circuit, and when the pixel circuit is turned on, a drive current from the data line is directly supplied to the first electrode to drive the sub-pixels to emit light.

3. The display panel according to claim 1, wherein each sub-pixel region comprises a light-emitting area and a pixel circuit area, and size of a projection area of the pillar on the sub-pixel region is less than 50% size of the area of a pixel region.

4. The display panel according to claim 1, wherein each side of the pillar is an arc.

5. The display panel according to claim 4, wherein the pillar is a cylindrical pillar or an elliptical cylindrical pillar.

6. The display panel according to claim 1, wherein the pixel circuit comprises only a switching device.

7. The display panel according to claim 6, wherein the pixel circuit comprises one switching device, and the switching device comprises a first terminal, a second terminal, and a control terminal; and the scanning line is connected to the control terminal of the switching device, the data line is connected to the first terminal of the switching device, and the first electrode is connected to the second terminal of the switching device.

8. The display panel according to claim 7, wherein the first electrode is an anode, the second electrode is a cathode, the switching device is a driving thin film transistor, and the first terminal is a source or a drain of the driving thin film transistor, the second terminal is a drain or a source of the driving thin film transistor, the control terminal is a gate of the driving thin film transistor; and the driving thin film transistor is a top gate structure or a bottom gate structure.

9. The display panel according to claim 1, wherein one or more of the first electrode, the second electrode, the data line, and the scanning line are made of a transparent conductive material and the light transmittance of the transparent conductive material is greater than 90%.

10. The display panel according to claim 9, wherein the scanning line and/or data line are made of an indium tin oxide material or an indium zinc oxide material.

11. The display panel according to claim 10, wherein when the gate is made of the transparent conductive material, the scanning line and the gate are formed in the same step; or
when the gate is made of a metal material, the scanning line is disposed above or below the gate.

12. The display panel according to claim 11, wherein the data line and the first electrode are formed in the same step.

13. The display panel according to claim 1, wherein a plurality of the scanning lines extend in parallel along a first direction, a plurality of the data lines extend in parallel along a second direction, the first direction intersects with the second direction and at least one side of the scanning line and/or the data line in the extending direction thereof has a wave shape.

14. The display panel according to claim 13, wherein a first pitch between adjacent scanning lines changes continuously or intermittently; and/or
a second pitch between adjacent data lines changes continuously or intermittently; and/or
the width of the scanning line changes continuously or intermittently; and/or
the width of the data line changes continuously or intermittently.

15. The display panel according to claim 14, wherein both sides of the scanning line in the extending direction have a wave shape, and wave peaks of the two sides are oppositely disposed, and wave troughs are oppositely disposed; and/or
two sides of the data line in the extending direction have a wave shape, and the wave peaks of the two sides are oppositely disposed, and the wave troughs are oppositely disposed.

16. The display panel according to claim 15, wherein a first connecting portion is formed at a corresponding position of the wave trough of the scanning line; and the first connecting portion is strip-shaped; and/or
a second connecting portion is formed at a corresponding position of the wave trough of the data line, and the second connecting portion is strip-shaped; and/or
the first connecting portion forming an electrical connecting area of the scanning line and the switching device; and/or
the second connecting portion forming an electrical connecting area of the data line and the switching device.

17. The display panel according to claim 1, wherein the first electrode is circular, elliptical or dumbbell shaped.

18. The display panel according to claim 17, wherein the sub-pixels are circular, elliptical or dumbbell shaped.

19. A display screen, comprising at least a first display area and a second display area, each display area being used for displaying a dynamic or static picture, and a photosensitive device being disposed below the first display area; wherein
the first display area is provided with a display panel comprising:
a substrate;
a pixel circuit, disposed on the substrate;
a first electrode layer, disposed on the pixel circuit and comprising a plurality of first electrodes;
a pixel defining layer, disposed on the first electrodes and having a plurality of openings thereon; a pillar, disposed on the pixel defining layer and at least partially covering an active layer and/or a metal layer in the pixel circuit;
a second electrode, disposed on a light emitting structure layer;
a scanning line and a data line, both connected to the pixel circuit;
wherein the pixel circuit has a one-to-one correspondence with the first electrodes, the light emitting structure layer is disposed in the openings of the pixel defining layer to form a plurality of sub-pixels, and the sub-pixel has a one-to-one correspondence with the first electrodes, and the pillar is made of a non-specular reflective material, the reflectivity of the non-specular reflective material of the pillar is less than the reflectivity of a metal material, and
the second display area is provided with a passive matrix organic light emitting diode display panel or an active matrix organic light emitting diode display panel.

20. A display terminal, comprising:
an apparatus body, having a device area;
a display screen, covering the apparatus body and comprising at least a first display area and a second display area, each display area being used for displaying a dynamic or static picture, and a photosensitive device being disposed below the first display area, wherein
the first display area is provided with a display panel, comprising:
a substrate,
a pixel circuit, disposed on the substrate,
a first electrode layer, disposed on the pixel circuit and comprising a plurality of first electrodes,
a pixel defining layer, disposed on the first electrodes and having a plurality of openings thereon, a pillar, disposed on the pixel defining layer and at least partially covering an active layer and/or a metal layer in the pixel circuit,
a second electrode, disposed on a light emitting structure layer,
a scanning line and a data line, both connected to the pixel circuit,
wherein the pixel circuit has a one-to-one correspondence with the first electrodes, the light emitting structure layer is disposed in the openings of the pixel defining layer to form a plurality of sub-pixels, and the sub-pixel has a one-to-one correspondence with the first electrodes, and the pillar is made of a non-specular reflective material, the reflectivity of the non-specular reflective material of the pillar is less than the reflectivity of a metal material
the display panel of claim 1, and
the second display area is provided with a passive matrix organic light emitting diode display panel or an active matrix organic light emitting diode display panel, and the display screen; wherein
the device area is located below the first display area and provided with a photosensitive device for collecting light through the first display area.
